(19) United States
(12) Patent Application Publication
(10) Pub. No.: US 2019/0106789 A1
(43) Pub. Date: Apr. 11, 2019

(54) FILM DEPOSITION APPARATUS

(71) Applicant: TOSHIBA MITSUBISHI-ELECTRIC INDUSTRIAL SYSTEMS CORPORATION, Chuo-ku (JP)

(72) Inventors: Hiroyuki ORITA, Tokyo (JP); Takahiro HIRAMATSU, Tokyo (JP)

(73) Assignee: TOSHIBA MITSUBISHI-ELECTRIC INDUSTRIAL SYSTEMS CORPORATION, Chuo-ku (JP)

(21) Appl. No.: 16/086,936

(22) PCT Filed: Apr. 26, 2016
(86) PCT No.: PCT/JP2016/063000

§ 371 Date: Sep. 20, 2018

(51) Int. Cl. C23C 16/54; C23C 16/448; C23C 16/458; C23C 16/46; H01L 21/677

(52) U.S. Cl. CPC C23C 16/54; C23C 16/4486; H01L 21/67706; C23C 16/46; C23C 16/458

(57) ABSTRACT

A film deposition apparatus includes substrate loading stages which place a substrate and include a suction mechanism for suctioning the placed substrate and a heating mechanism for heating the placed substrate. A substrate transferring mechanism executes a transporting operation for causing the substrate loading stages to sequentially pass through an injection region of a thin film forming nozzle at a moving speed. The transporting operation includes a circulating transporting treatment for circulating and arranging one substrate loading stage of the substrate loading stages causing all the placed substrates to pass through the injection region at a circulating speed behind the other substrate loading stage.

### TECHNICAL FIELD

The present invention relates to a film deposition apparatus which is used for a solar cell, an electronic apparatus or the like and deposits a thin film on a substrate.

### BACKGROUND ART

Conventionally, in order to achieve high treatment capability (throughput) in a film deposition apparatus for forming a thin film on the entire surface of a substrate while transporting the substrate, it is necessary to continuously transport a film deposition substrate under a film deposition treatment environment without temporal gaps.

Therefore, in a conventional film deposition apparatus which transports a substrate, generally, a plurality of substrates are transported by a conveyor or the like, and a thin film is deposited on each of the substrates while a heating treatment is performed by a separately provided heating mechanism during a film deposition treatment or during transportation. Examples of the film deposition apparatus include a tray type in-line film deposition apparatus disclosed in Patent Document 1. In the film deposition apparatus, a tray on which a substrate is placed is transported by a roller conveyer. Another film deposition apparatus causing a roller conveyer to transport a substrate is a sputtering apparatus disclosed in Patent Document 2.

A semiconductor manufacturing apparatus which includes a heating mechanism, includes a plurality of heater blocks loading a substrate, and circulates the heater blocks is disclosed in, for example, Patent Document 3. The semiconductor manufacturing apparatus circulates a large number of heater blocks, to allow a heating treatment to be relatively slowly performed while high treatment capability is measured.

### PRIOR ART DOCUMENTS

### Patent Documents

Patent Document 1: Japanese Patent Application Laid-Open No. 9-279341 (1997)

Patent Document 2: International Publication No. WO2013/183202

Patent Document 3: Japanese Patent Application Laid-Open No. 63-166217 (1988)

### SUMMARY

### Problem to be Solved by the Invention

However, in the film deposition apparatus disclosed in Patent Document 1, the substrate is merely placed on the tray by its own weight, so that, if the substrate (and the tray) is rapidly heated during the film deposition treatment in this state, the temperature gradient (between the upper surface and the lower surface) in the substrate is increased, which causes occurrence of warpage or cracking in the substrate. The sputtering apparatus disclosed in Patent Document 2 does not disclose the heating mechanism, and is unsuitable as the film deposition apparatus requiring the heating treatment.

The semiconductor manufacturing apparatus disclosed in Patent Document 3 makes it necessary to include a large number of (8 or more in FIG. 1) heater blocks in order to continuously transport the heater blocks to below a gas supply nozzle. Furthermore, the semiconductor manufacturing apparatus causes complicated connection of power supply wires and vacuum pipes for a large number of heater blocks, which causes increased cost of the apparatus. When the number of the heater blocks is increased, there is a concern that a film deposition treatment time becomes unnecessarily long, which causes lowered treatment capability during film deposition.

In addition, the semiconductor manufacturing apparatus performs the heating treatment in a state where the substrate (wafer) is simply placed on the heater blocks, which causes warpage or cracking in the substrate as soon as a temperature gradient occurs in the substrate. When warpage or cracking occurs in the substrate, the flatness of the substrate is lost, which causes deteriorated uniformity of film deposition quality.

The present invention solves the above-mentioned problems, and it is an object of the present invention to provide a film deposition apparatus which effectively suppresses a phenomenon in which warpage or cracking occurs in a film deposition substrate while minimizing the cost of the apparatus, and can exhibit high treatment capability.

### Means to Solve the Problem

A film deposition apparatus according to the present invention includes: first and second substrate placing portions which place a substrate and include a suction mechanism for suctioning the placed substrate and a heating mechanism for heating the placed substrate; a film deposition treatment executing portion which executes a film deposition treatment for depositing a thin film for the substrate placed on a substrate placing portion in a film deposition treatment region; and a substrate placing portion transferring device which executes a transporting operation for moving the first and second substrate placing portions to cause the substrate placing portions to sequentially pass through the film deposition treatment region at a moving speed during film deposition, wherein the transporting operation includes a circulating transporting treatment for circulating and arranging one substrate placing portion of the first and second substrate placing portions causing all the placed substrates to pass through the film deposition treatment region at a circulating speed behind the other substrate placing portion.

### Effects of the Invention

The first and second substrate placing portions of the film deposition apparatus according to the present invention each have the suction mechanism and the heating mechanism, and can heat the substrate placed in a preparation period until reaching the film deposition treatment region while suctioning the substrate, so that the necessity of rapidly heating the substrate is eliminated, and the heating treatment can be executed in a state where the substrate is suctioned by the suction mechanism. This can effectively suppress the phenomenon of occurrence of warpage by the temperature gradient in the substrate during the heating treatment.

In addition, the substrate placing portion transferring device executes the circulating transporting treatment for circulating and arranging one substrate placing portion passing through the film deposition treatment region at a circulating speed behind the other substrate placing portion. This makes it possible to efficiently move the first and second substrate placing portions while circulating the first and second substrate placing portions to sequentially pass through the film deposition treatment region, so that the treatment capability in the film deposition treatment can be improved.

Furthermore, in the film deposition apparatus of the present invention, the minimum number of the substrate placing portions is set to 2 (first and second substrate loading portions), so that the cost of the apparatus can be minimized.

The objects, features, aspects, and advantages of the present invention will become more apparent from the following detailed description and the accompanying drawings.

### BRIEF DESCRIPTION OF DRAWINGS

FIG. 1 is an illustration diagram showing a schematic configuration of a film deposition apparatus according to an embodiment of the present invention.

FIG. 2 is a cross-sectional view schematically showing a substrate transferring mechanism and its periphery.

FIG. 3 is an illustration diagram (part 1) showing a transporting operation of two substrate loading stages in the film deposition apparatus of the present embodiment.

FIG. 4 is an illustration diagram (part 2) showing a transporting operation of two substrate loading stages in the film deposition apparatus of the present embodiment.

FIG. 5 is an illustration diagram (part 3) showing a transporting operation of two substrate loading stages in the film deposition apparatus of the present embodiment.

FIG. 6 is an illustration diagram (part 4) showing a transporting operation of two substrate loading stages in the film deposition apparatus of the present embodiment.

FIG. 7 is an illustration diagram (part 5) showing a transporting operation of two substrate loading stages in the film deposition apparatus of the present embodiment.

FIG. 8 is an illustration diagram (part 6) showing a transporting operation of two substrate loading stages in the film deposition apparatus of the present embodiment.

FIG. 9 is an illustration diagram (part 7) showing a transporting operation of two substrate loading stages in the film deposition apparatus of the present embodiment.

FIG. 10 is an illustration diagram schematically showing a configuration of a conventional film deposition apparatus.

### DESCRIPTION OF EMBODIMENTS

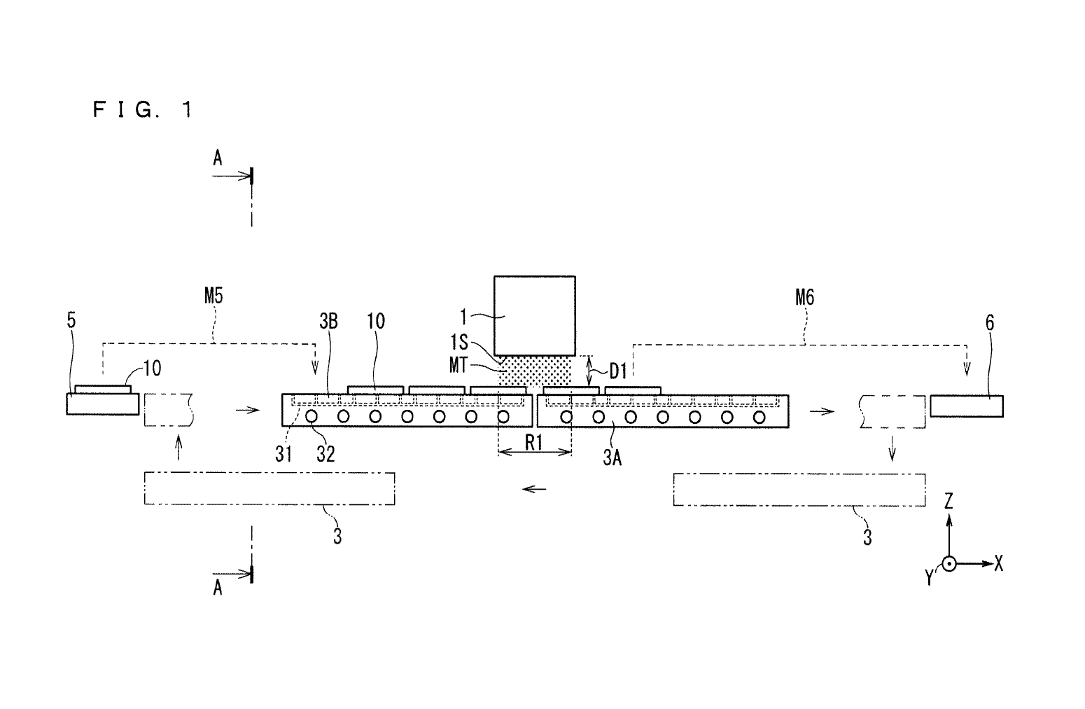

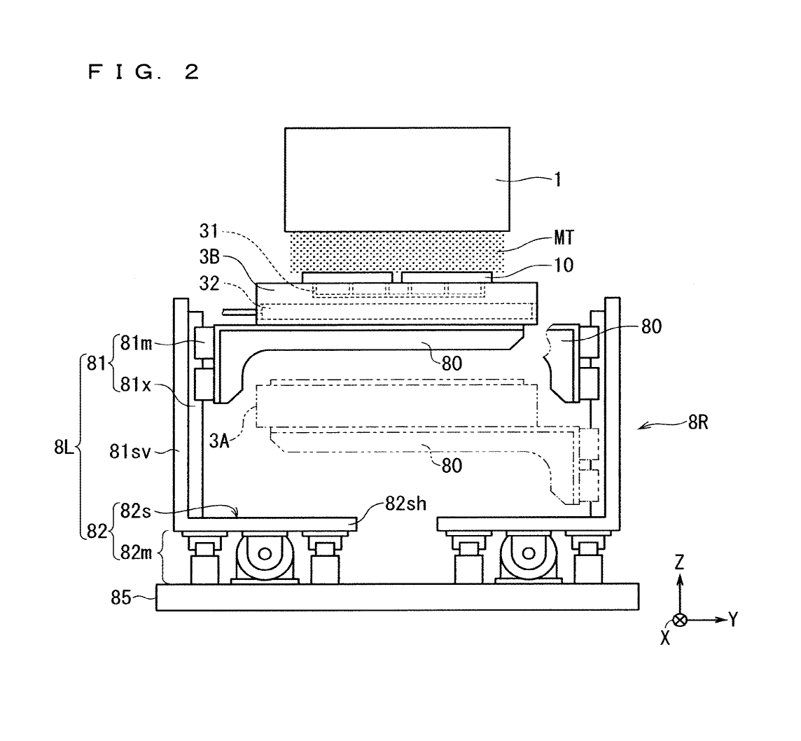

FIG. 1 is an illustration diagram showing a schematic configuration of a film deposition apparatus according to an embodiment of the present invention. As shown in FIG. 1, a plurality of substrates 10 are placed on an upper surface of each of substrate loading stages 3A and 3B (first and second substrate placing portions). FIG. 1, and FIGS. 2 to 10 to be shown below show an XYZ orthogonal coordinate system.

Each of the substrate loading stages 3A and 3B includes suction mechanisms 31 according to vacuum suction. The suction mechanisms 31 allow the entire lower surface of each of the plurality of placed substrates 10 to be suctioned onto the upper surface of each of the substrate loading stages 3A and 3B. Furthermore, each of the substrate loading stages 3A and 3B includes heating mechanisms 32 below the suction mechanism 31. The heating mechanisms 32 can execute a heating treatment for the plurality of substrates 10 placed on the upper surface.

Hereinafter, the substrate loading stages 3A and 3B are sometimes collectively referred to as a “substrate loading stage 3”.

A thin film forming nozzle 1 (mist injecting portion) functioning as a film deposition treatment executing portion injects a raw material mist MT downward from an injecting port provided on an injecting surface 1S, thereby executing a film deposition treatment for depositing a thin film on the substrate 10 placed on the upper surface of the substrate loading stage 3 in an injection region R1 (film deposition treatment region). In this case, a mist injecting distance D1, which is a distance (vertical distance along the Z direction) between the injecting surface 1S and the substrate 10 in the injection region R1, is set to 1 mm or more and 30 mm or less. The periphery of the injection region R1 is generally covered with a chamber (not shown) or the like.

A heating treatment provided by the heating mechanism 32 of the substrate loading stage 3 is executed during the film deposition treatment and before and after the film deposition treatment. In the present embodiment, a heating temperature during the heating treatment provided by the heating mechanism 32 is about 400° C.

The raw material mist MT is a mist obtained by misting a raw material solution, and can be injected into the air.

The substrate loading stages 3A and 3B are transported by a substrate transferring mechanism 8 (substrate placing portion transferring device) to be described later. The substrate transferring mechanism 8 executes a transporting operation for moving the substrate loading stages 3A and 3B to cause the substrate loading stages 3A and 3B to sequentially pass through the injection region R1 at a speed V0 (moving speed during film deposition).

The transporting operation includes a circulating transporting treatment for circulating and arranging one of the substrate loading stages 3A and 3B (for example, the substrate loading stage 3A) at a circulating speed behind the other substrate loading stage (for example, substrate loading stage 3B). The substrate loading stage 3A is a substrate placing portion causing all the placed substrates 10 to pass through the injection region R1.

On a substrate introducing portion 5 provided on the upstream side of the thin film forming nozzle 1, the substrate 10 before the film deposition treatment is placed. The substrate 10 on the substrate introducing portion 5 is arranged on the upper surface of the substrate loading stage 3 by a substrate introducing operation M5 provided by a suction gripper 4A to be described later.

A substrate retrieving portion 6 is provided on the downstream side of the thin film forming nozzle 1. The substrate 10 after the film deposition treatment on the substrate loading stage 3 is arranged on the substrate retrieving portion 6 by a substrate retrieving operation M6 provided by a suction gripper 4B (second gripper) to be described later.

Herein, a transport direction (+X direction) side when the substrate loading stages 3A and 3B pass though the injection region R1 with respect to the thin film forming nozzle 1 is defined as a downstream side, and a counter transport direction (−X direction) side which is a direction opposite to the transport direction is defined as an upstream side.

FIG. 2 is a cross-sectional view schematically showing the substrate transferring mechanism 8 and its periphery in the A-A cross-section of FIG. 1. The substrate transferring mechanism 8 provided on a support plate 85 is constituted by the combination of a transferring mechanism 8L and a transferring mechanism 8R which are operated independently of each other. The transferring mechanism 8R is provided for transporting the substrate loading stage 3A. The transferring mechanism 8L is provided for transporting the substrate loading stage 3B. The support plate 85 has a planar shape including at least a transporting plane area defined by an XY plane requiring a transporting operation provided by the substrate introducing portion 5.

The transferring mechanism 8L includes an elevating mechanism 81 and a traverse mechanism 82. The traverse mechanism 82 includes a supporting member 82s having an L-shaped cross section and a moving mechanism 82m provided on the lower surface of a horizontal plate 82sh (L-shaped cross bar portion) of the supporting member 82s. The moving mechanism 82m includes, for example, a direct acting guide and a power transmission screw, and is provided so as to be movable along the X direction on the support plate 85 by the driving force of a motor.

The elevating mechanism 81 includes an elevating member 81m and an elevating shaft 81x. The elevating shaft 81x is erected and fixedly attached to a vertical plate 82sv (L-shaped vertical bar portion) of the supporting member 82s. The elevating member 81m is attached to the elevating shaft 81x so as to be freely elevated. A stage fixing member 80 is provided in connection with the elevating member 81m, and the lower surface of the substrate loading stage 3B is fixed on the upper surface of the stage fixing member 80.

The elevating operation of the elevating member 81m is considered to be, for example, an operation in which the rotational driving force of a rotational driving portion (not shown) transmitted as vertical movement to a transmission mechanism such as a chain (not shown) which is provided in the elevating shaft 81x and is connected to the elevating member 81m. As a result, the elevating operation of the elevating member 81m can be achieved by the vertical movement of the above-described transmission mechanism.

Therefore, the transferring mechanism 8L can move the substrate loading stage 3B along the transport direction (+X direction) or move the substrate loading stage 3B along the counter transport direction (−X direction), according to a traverse operation along the X direction (+X direction or −X direction) of the moving mechanism 82m.

Furthermore, the transferring mechanism 8L can raise and lower the substrate loading stage 3B according to the elevating operation along the Z direction (+Z direction or −Z direction) of the elevating member 81m.

The transferring mechanism 8R is provided symmetrically with the transferring mechanism 8L with respect to a ZX plane in FIG. 2, and has a structure equivalent to that of the transferring mechanism 8L. Therefore, as with the transferring mechanism 8L, the transferring mechanism 8R can move the substrate loading stage 3A along the transport direction and the counter transport direction according to the traverse operation of the traverse mechanism 82, and raise and lower the substrate loading stage 3A according to the elevating operation of the elevating mechanism 81. The positions of the substrate loading stages 3A and 3B in a Y direction are not changed according to the traverse operations and elevating operations of the transferring mechanisms 8L and 8R described above.

Thus, in the transferring mechanism 8L and the transferring mechanism 8R, the vertical plate 82sv of the supporting member 82s and the elevating shaft 81x are formed at different positions in the Y direction. However, in both the transferring mechanism 8L and the transferring mechanism 8R, a cantilever support structure supports the substrate loading stage 3B and the substrate loading stage 3A. Therefore, by suitably combining the above-described traverse operation and elevating operation, transporting operations (including a circulating transporting treatment) can be executed independently of each other without causing interference between the substrate loading stages 3A and 3B.

In the example shown in FIG. 2, two substrates 10 can be placed along the Y direction on the substrate loading stage 3.

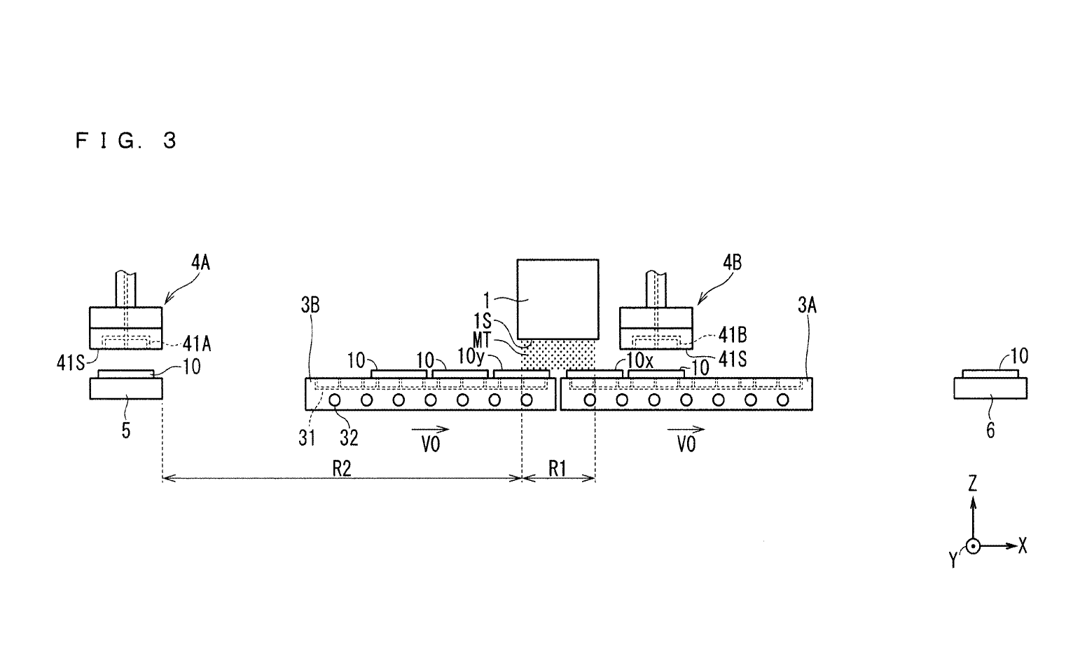

FIGS. 3 to 9 are illustration diagrams showing the transporting operations of the substrate loading stages 3A and 3B provided by the film deposition apparatus of the present embodiment. The transporting operation is performed by the substrate transferring mechanism 8 (transferring mechanism 8L+transferring mechanism 8R) shown in FIG. 2.

As shown in FIG. 3, by the traverse operations of the transferring mechanisms 8R and 8L, both the substrate loading stages 3A and 3B are transported in the transport direction (+X direction) at a speed V0. The raw material mist MT is injected onto the substrates 10 on the upper surfaces of the substrate loading stages 3A and 3B in the injection region R1, to execute a film deposition treatment for depositing a thin film on the upper surface of the substrate 10. In FIG. 3 and FIGS. 4 to 9 to be shown below, a region located on a further upstream side with respect to the injection region R1 is defined as a film depositing preparation region R2.

In the state shown in FIG. 3, both a rearmost substrate 10x on the substrate loading stage 3A and a frontmost substrate 10y on the substrate loading stage 3B are present in the injection region R1. On the upper surface of the substrate loading stage 3B, the substrate 10 located on the upstream side with respect to the substrate 10y is present in the film depositing preparation region R2, and is in a state before the film deposition treatment.

However, the substrate loading stage 3B includes the heating mechanism 32, so that a heating treatment can be executed even under a condition that the substrate 10 is present in the film depositing preparation region R2. At that time, by the suction mechanism 31, the entire lower surface of the substrate 10 is suctioned onto the upper surface of the substrate loading stage 3B, so that the substrate 10 is not warped or cracked even if a slight temperature gradient occurs in the substrate 10 by the heating treatment.

The substrate 10 before the film deposition treatment placed on the substrate introducing portion 5 is appropriately arranged on the upper surface of the substrate loading stage 3B (present in the film depositing preparation region R2) by the substrate introducing operation M5 provided by the suction gripper 4A (first gripper). The substrate 10 after the film deposition treatment which has passed through the injection region R1 on the substrate loading stage 3A is arranged on the substrate retrieving portion 6 by the substrate retrieving operation M6 provided by the suction gripper 4B.

Hereinafter, the substrate introducing operation M5 will be described in detail. First, the suction gripper 4A (first gripper) causes the suction mechanism 41A to suction the substrate 10 placed on the substrate introducing portion 5 to grip the substrate 10. In a state where the substrate 10 is grasped, the suction gripper 4A is moved to above the substrate unloaded region where the substrate of the substrate loading stage 3 is not placed (the position where the substrate 10 can be placed on the upper surface of the substrate loading stage 3A by releasing the suction of the substrate 10 by the suction mechanism 41A). In this state, a substrate releasing treatment for releasing the gripping state of the substrate 10 provided by the suction mechanism 41A of the suction gripper 4A is executed, and the substrate 10 is arranged on the substrate unloaded region of the substrate loading stage 3. The above operation is the substrate introducing operation M5. The suction mechanism 41A suctions the substrate 10 according to vacuum suction, and the substrate releasing treatment is performed by blowing releasing gas from the suction mechanism 41A onto the substrate.

Next, the substrate retrieving operation M6 will be described in detail. First, the suction gripper 4B (second gripper) is moved to above the substrate 10 after the film deposition treatment which has passed through the injection region R1. In this state, a suction mechanism 41B suctions the upper surface of the substrate 10 on the substrate loading stage 3 to the gripping surface 41S so as to grip the substrate 10. In a state where the substrate 10 is gripped, the suction gripper 4B is moved to above the substrate unloaded region of the substrate retrieving portion 6 where the substrate is not placed (the position where the suction mechanism 41B can suction the substrate 10). In this state, the substrate releasing treatment for releasing the gripping state of the substrate 10 on the gripping surface 41S by the suction mechanism 41B of the suction gripper 4B is executed, to arrange the substrate 10 on the substrate unloaded region of the substrate retrieving portion 6. The above operation is the substrate retrieving operation M6. The suction mechanism 41B suctions the substrate 10 according to vacuum suction, and the substrate releasing treatment is performed by blowing releasing gas from the suction mechanism 41B onto the upper surface of the substrate.

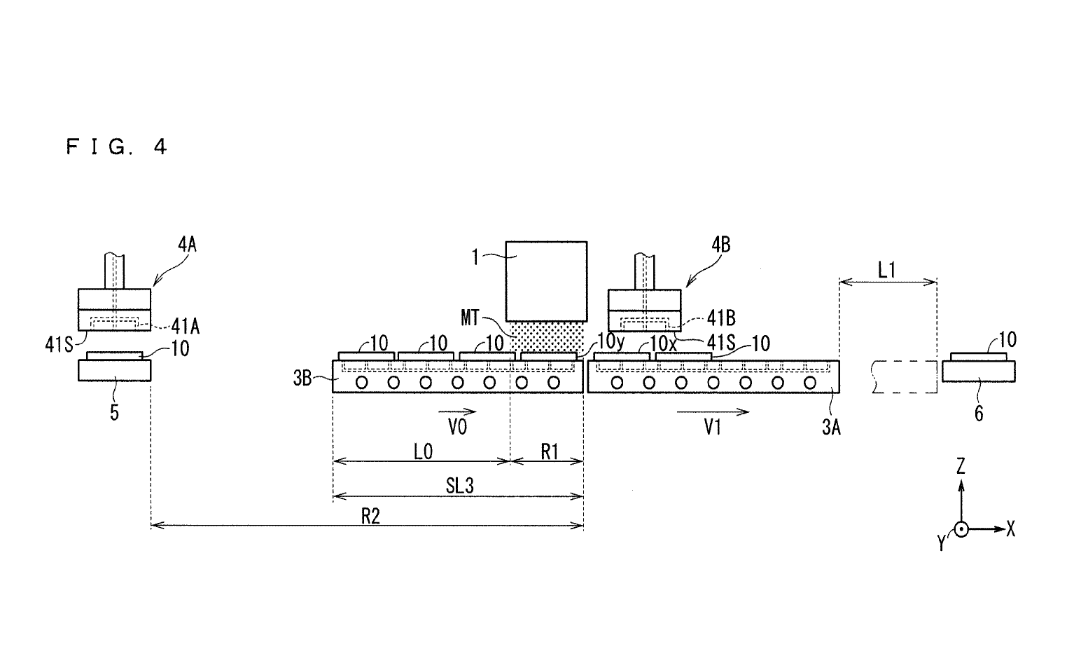

Thereafter, as shown in FIG. 4, when the rearmost substrate 10x on the upper surface of the substrate loading stage 3A passes through the injection region R1, all the substrates 10 placed on the upper surface of the substrate loading stage 3A pass through the injection region R1.

The circulating transporting treatment for the substrate loading stage 3A in this state is executed at speeds V1 to V5 (circulating speeds). First, the transferring mechanism 8R raises a transport speed according to the traverse operation from the speed V0 to the speed V1 (>V0). At this time, all the substrates 10 on the upper surface of the substrate loading stage 3A are moved onto the substrate retrieving portion 6 by the substrate retrieving operation M6 provided by the suction gripper 4B.

On the other hand, the substrate loading stage 3B maintains the transporting speed of the speed V0 according to the traverse operation of the transferring mechanism 8L.

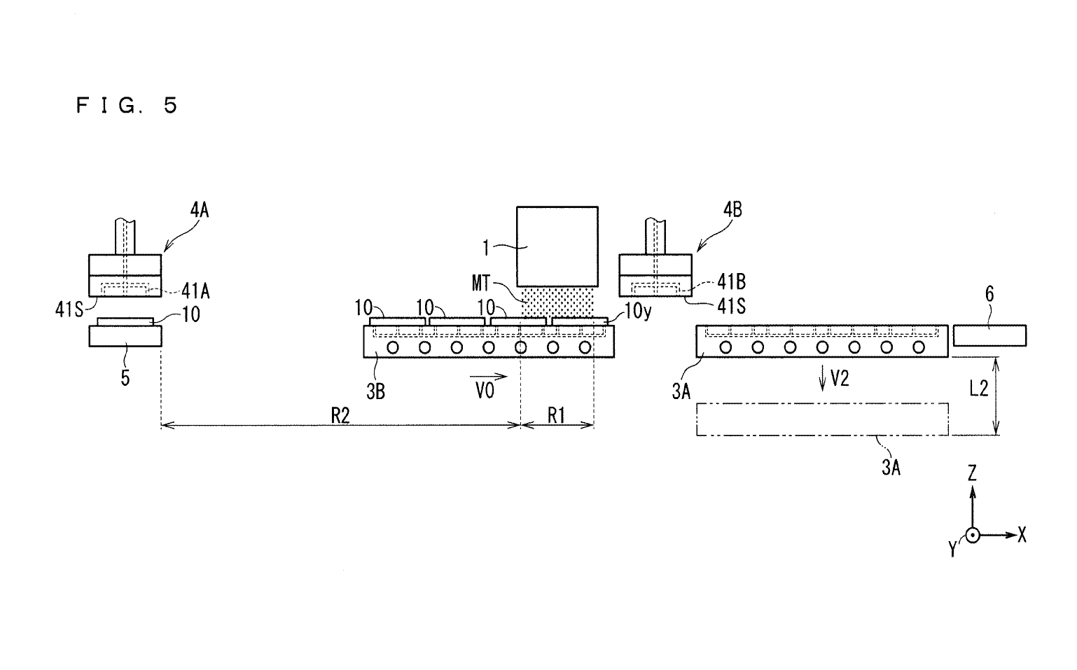

Then, as shown in FIG. 5, after all the substrates 10 on the upper surface of the substrate loading stage 3A are retrieved, the transferring mechanism 8R switches from the traverse operation to the elevating operation, and lowers the substrate loading stage 3A at the speed V2 (>V0). On the other hand, the substrate loading stage 3B on which the substrate 10 is present in the injection region R1 is transported along the transport direction at the speed V0 by the traverse operation of the transferring mechanism 8L.

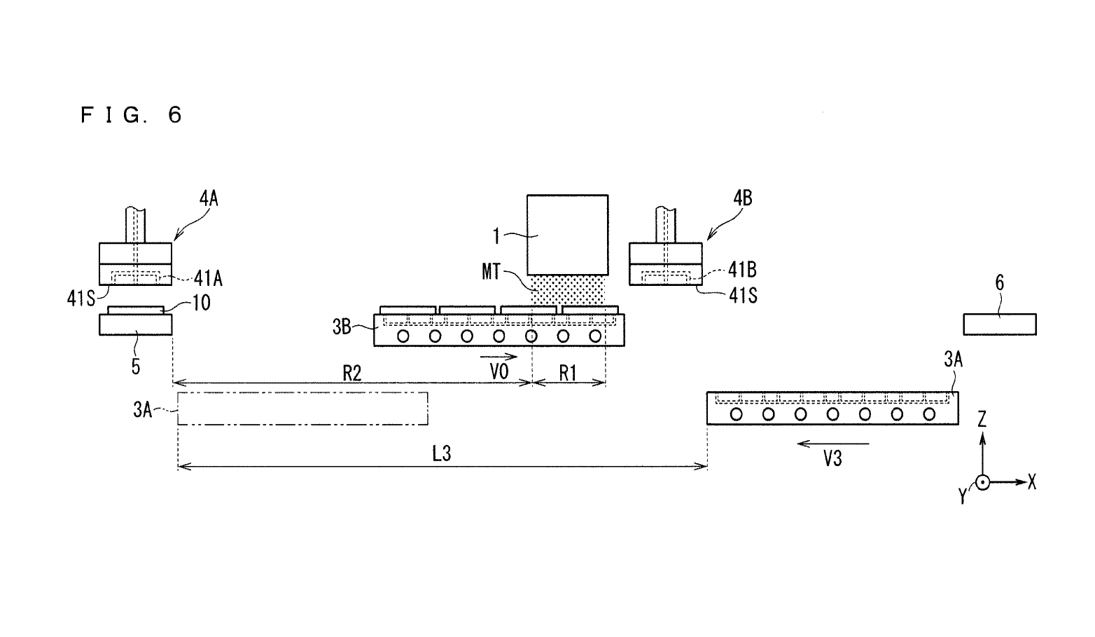

Thereafter, as shown in FIG. 6, by lowering the substrate loading stage 3A, a difference in height is provided between the substrate loading stages 3A and 3B such that the substrate loading stages 3A and 3B do not interfere with each other in the Z direction. The transferring mechanism 8R then switches from the elevating operation to the traverse operation.

The substrate loading stage 3A is horizontally moved along the counter transport direction (−X direction) at the speed V3 (>V0) by the traverse operation of the transferring mechanism 8R. On the other hand, the substrate loading stage 3B on which the substrate 10 is present in the injection region R1 is transported at the speed V0 along the transport direction.

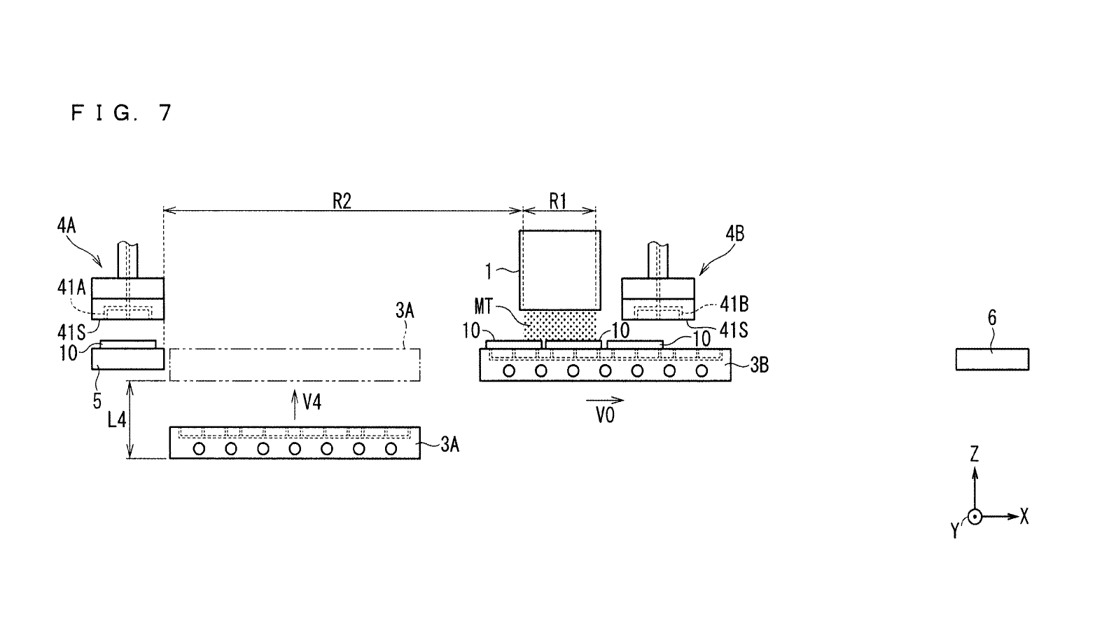

Thereafter, as shown in FIG. 7, the substrate loading stage 3A is horizontally moved to the upstream side which does not interfere with the substrate loading stage 3B in the X direction, and the transferring mechanism 8R then switches from the traverse operation to the elevating operation.

The substrate loading stage 3A is raised at the speed V4 (>V0) by the elevating operation of the transferring mechanism 8R. On the other hand, the substrate loading stage 3B on which the substrate 10 is present in the injection region R1 is transported along the transport direction at the speed V0.

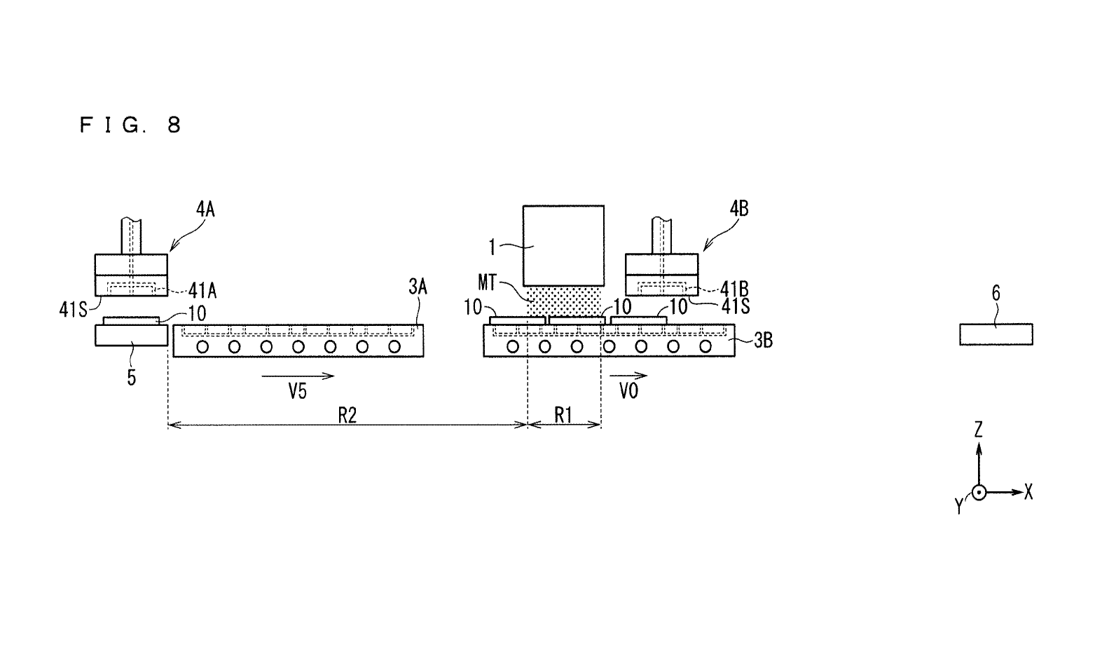

Next, as shown in FIG. 8, the substrate loading stage 3A reaches the same height as that of the substrate loading stage 3B, and the transferring mechanism 8R then switches from the elevating operation to the traverse operation.

The substrate loading stage 3A is transported at the speed V5 (>V0) along the transport direction by the traverse movement of the transferring mechanism 8R. At this time, the substrate 10 before the film deposition treatment is appropriately arranged on the upper surface of the substrate loading stage 3A by the substrate introducing operation M5 provided by the suction gripper 4A. On the other hand, the substrate loading stage 3B on which the substrate 10 is present in the injection region R1 is transported at the speed V0 along the transport direction.

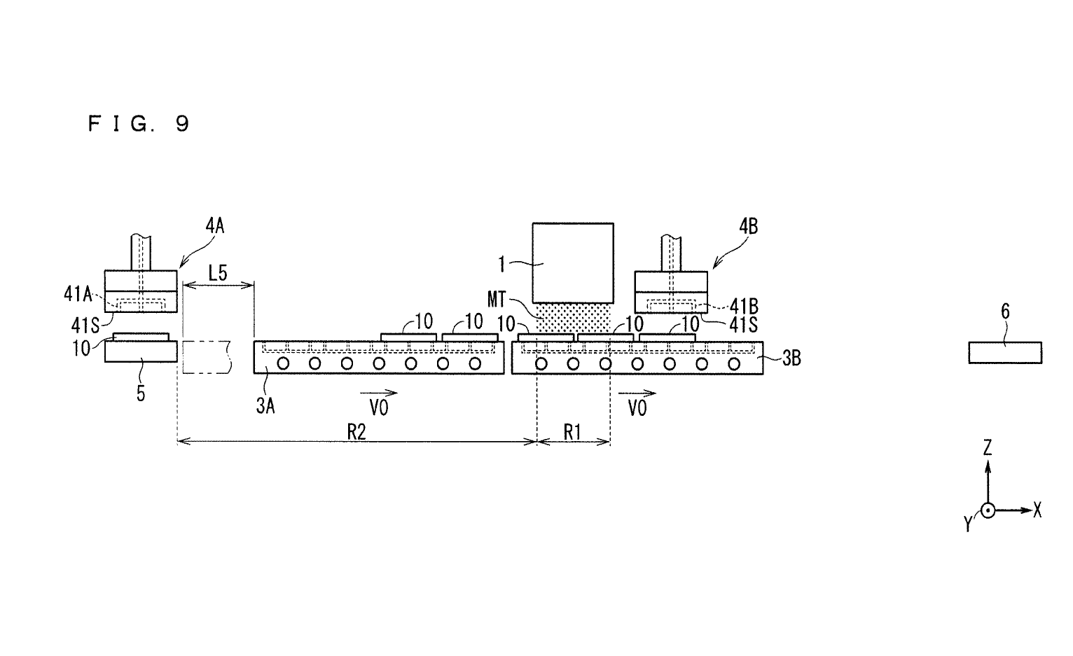

Then, as shown in FIG. 9, when the substrate loading stage 3A is arranged at a minimum interval behind the substrate loading stage 3B, the circulating transporting treatment is completed.

Thus, the circulating transporting treatment is executed by the combinations of the movement in the +X direction (horizontal movement in the transport direction) at the speed V1, the movement in the −Z direction (lowering movement) at the speed V2, the movement in the −X direction (horizontal movement in the counter transport direction) at the speed V3, the movement in the +Z direction (raising movement) at the speed V4, and the movement in the +X direction (horizontal movement in the transport direction) at the speed V5. The circulating transporting treatment is completed until all the plurality of substrates 10 on the upper surface of the substrate loading stage 3B (the other substrate placing portion) pass through the injection region R1.

In the substrate loading stage 3A for which the circulating transporting treatment is completed, the transferring mechanism 8R lowers the transport speed provided by the traverse movement from the speed V5 to the speed V0.

As a result, the substrate loading stage 3A is transported along the transport direction at the speed V0 (moving speed during film deposition). Thereafter, when it is necessary to place the substrate 10 on the substrate loading stage 3A, by the substrate introducing operation M5 provided by the suction gripper 4A, the substrate 10 before the film deposition treatment is appropriately arranged on the upper surface of the substrate loading stage 3A (present in the film depositing preparation region R2).

On the other hand, the substrate loading stage 3B which is partially present in the injection region R1 is transported along the transport direction at the speed V0.

Thereafter, after all the substrates 10 on the upper surface of the substrate loading stage 3B have passed through the injection region R1, the circulating transporting treatment is executed for the substrate loading stage 3B as with the substrate loading stage 3A shown in FIGS. 4 to 9. At this time, the substrate loading stage 3A is transported at the speed V0 along the transport direction.

Thus, while the two substrate loading stages 3A and 3B are sequentially circulated by the substrate transferring mechanism 8 including the transferring mechanisms 8L and 8R, the transporting operation (including the circulating transporting treatment) for the substrate loading stages 3A and 3B is executed so that the substrate 10 before the film deposition treatment is always present in the injection region R1.

The substrate loading stages 3A and 3B (first and second substrate placing portions) in the film deposition apparatus of the present embodiment include the suction mechanism 31 and the heating mechanism 32, respectively. The substrate 10 before the film deposition treatment placed in a preparation period present in the film depositing preparation region R2 is heated until the substrate loading stages 3A and 3B reach the injection region R1 (film deposition treatment region), to eliminate the necessity of rapidly heating the substrate 10. In addition, the heating treatment is executed in a state where the lower surface of the substrate 10 is suctioned by the suction mechanism 31 included in the substrate loading stage 3. As a result, the film deposition apparatus of the present embodiment suppresses the temperature gradient occurring in the substrate 10 during the heating treatment low. Furthermore, the film deposition apparatus heats the substrate 10 in a state where the substrate 10 is suctioned, which makes it possible to effectively suppress the occurrence of warpage or cracking of the substrate 10.

In addition, the substrate transferring mechanism 8 (substrate placing portion transferring device) including the transferring mechanisms 8L and 8R executes the circulating transporting treatment for arranging one substrate loading stage 3 which has passed through the injection region R1 (the substrate loading stage 3A in FIGS. 3 to 9) at circulating speeds V1 to V5 behind the other substrate loading stage 3 (substrate loading stage 3B in FIGS. 3 to 9). As a result, the substrate loading stages 3A and 3B are efficiently moved while the substrate loading stages 3A and 3B are circulated, to allow the placed substrate 10 to sequentially pass through the injection region R1, so that the treatment capability in the film deposition treatment can be improved.

Furthermore, in the present embodiment, the number of substrate loading stages 3 each including the suction mechanism 31 and the heating mechanism 32 is suppressed to the minimum of 2 (substrate loading stages 3A and 3B), which can achieve the substrate transferring mechanism 8 with a relatively simple configuration including the transferring mechanisms 8R and 8L for independently moving the substrate loading stages 3A and 3B, respectively. Therefore, the film deposition apparatus of the present embodiment can minimize the cost of the apparatus.

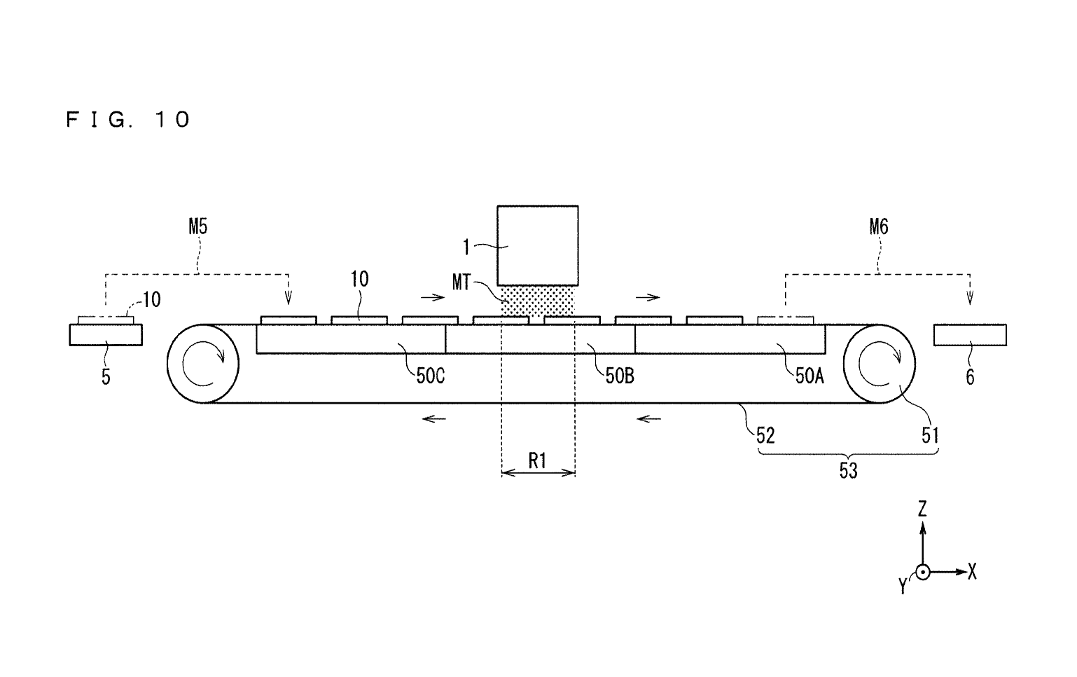

FIG. 10 is an illustration diagram schematically showing a configuration of a conventional film deposition apparatus when a transporting treatment for a plurality of substrates 10 is performed by a conventional conveyer 53.

As shown in FIG. 19, by a conveyor 53 including a roller 51 and a belt 52, a plurality of substrates 10 on the belt 52 are transported along a transport direction (X direction). In the conventional film deposition apparatus, three heating stages 50A to 50C are provided below the belt 52, so that a heating treatment for heating the substrate 10 via the belt 52 is performed.

As with the present embodiment, a raw material mist MT is injected from a thin film forming nozzle 1 in an injection region R1. The substrate 10 on a substrate introducing portion 5 on an upstream side is placed on the belt 52 by a substrate introducing operation M5. The substrate 10 on the belt 52 after passing through the injection region R1 is retrieved onto a substrate retrieving portion 6 on a downstream side by a substrate retrieving operation M6.

In the conventional film deposition apparatus, the conveyor 53 allows the plurality of substrates 10 to sequentially pass through the injection region R1. By providing the three heating stages 50A to 50C, the heating treatment for the substrate 10 can be executed in a relatively long period of time before, during, and after the film deposition treatment.

However, in the conventional film deposition apparatus shown in FIG. 10, the substrate 10 is merely placed on the belt 52, so that a temperature gradient occurs in the substrate 10 during the heating treatment provided by the heating stages 50A to 50C, which causes warpage.

Furthermore, in order to achieve a long-term heating treatment for the substrate 10, it is necessary to provide three relatively large heating stages 50A to 50C, which causes increased cost of the apparatus.

Thus, the film deposition apparatus of the present embodiment can exhibit high treatment capability without causing warpage or cracking in the substrate 10 to be film-deposited while minimizing the cost of the apparatus, which exhibits an effect unattainable in the conventional film deposition apparatus.

By setting the circulating speeds V1 to V5 to be higher than the moving speed during film deposition V0 in the film deposition apparatus of the embodiment, one substrate loading stage 3 can be promptly arranged behind the other substrate loading stage 3 by the circulating transporting treatment. The above effect can be achieved by setting at least the average value of the whole of the circulating speeds V1 to V5 to be higher than the moving speed during film deposition V0.

Hereinafter, the speed V0 and the circulating speeds V1 to V5 will be described in detail. Here, distances L0 to L5 related to the speeds V0 to V5 will be described.

As shown in FIG. 4, a distance obtained by subtracting the length of the injection region R1 from a formation length SL3 of the substrate loading stage 3 in the transport direction (X direction) is defined as a distance L0, and a horizontal distance before and after the substrate loading stage 3A performs the horizontal movement operation at the speed V1 in the transport direction is defined as a distance L1.

As shown in FIG. 5, a difference in height before and after the substrate loading stage 3A performs a lowering operation at the speed V2 is defined as a distance L2. Furthermore, as shown in FIG. 6, a horizontal distance before and after the substrate loading stage 3A performs is the horizontal movement operation at the speed V3 in the counter transport direction is defined as a distance L3.

Furthermore, as shown in FIG. 7, a difference in height before and after the substrate loading stage 3A performs the raising operation at a speed V4 is defined as a distance L4. As shown in FIG. 9, a horizontal distance before and after the substrate loading stage 3A performs the horizontal movement operation at a speed V5 is defined as a distance L5.

Therefore, in the operation example of the film deposition apparatus of the embodiment shown in FIGS. 3 to 9, it is necessary to satisfy the following expression (1) in order to complete the circulating transporting treatment for the substrate loading stage 3A (one of the substrate placing portions) until all the substrates 10 placed on the substrate loading stage 3B (the other substrate placing portion) pass through the injection region R1 which is the film deposition treatment region.

L0/V0≥L1/V1+L2/V2+L3/V3+L4/V4+L5/V5 (1)

In this case, the distance L0 is determined by the formation length SL3 in the transport direction of the substrate loading stage 3 when the injection region R1 is predetermined. The number of the substrates 10 to be placed on the upper surface (the number of substrates to be placed) is determined by the formation length SL3 of the substrate loading stage 3.

When the distances L1 to L5 and the speeds V0 to V5 are previously set in consideration of the film deposition treatment time and the scale of the film deposition apparatus or the like, the maximum number of the substrates 10 which can be placed on the upper surface of the substrate loading stage 3 having the minimum formation length SL3 satisfying the expression (1) is the optimum number of the substrates to be placed.

For example, provided that the minimum formation length SL3 along the X direction which satisfies the expression (1) is 800 mm when a rectangular substrate 10 having a side of 156 mm is used, five substrates 10 can be placed on along the X direction on the substrate loading stage 3 having the formation length SL3 of 800 mm in the X direction, so that the optimum number of the substrates to be placed is 10 (5×2) when two substrates 10 can be placed along the Y direction as shown in FIG. 2.

Thus, on each of the substrate loading stages 3A and 3B (first and second substrate placing portions) of the film deposition apparatus of the present embodiment, the substrates 10 of the optimum number (predetermined number) are loaded. That is, the optimum number of the substrates to be placed is set so that the circulating transporting treatment of one substrate placing portion (substrate loading stage 3A in FIGS. 3 to 9) is completed until all the substrates 10 on the other substrate placing portion (the substrate loading stage 3B in FIGS. 3 to 9) pass through the injection region R1 which is the film deposition treatment region.

In the embodiment, by arranging the substrates 10 of the optimum number on the upper surface of each of the substrate loading stages 3A and 3B, the transporting operation allows the substrates 10 placed on the upper surfaces of the substrate loading stages 3A and 3B to continuously reach the injection region R1, so that the improvement in the treatment capability in the film deposition treatment can be maximally exhibited.

A silicon substrate can be considered as the substrate 10. In this case, the film deposition apparatus of the present embodiment makes it possible to effectively suppress the occurrence of warpage by the temperature gradient in the silicon substrate during the film deposition treatment.

In the present embodiment, the thin film forming nozzle 1 (mist injecting portion) is used as a film deposition treatment executing portion, and the film deposition treatment region is the injection region R1.

Therefore, the film deposition apparatus of the embodiment can effectively suppress the occurrence of warpage by the temperature gradient in the substrate 10 during the film deposition treatment provided by injecting the raw material mist MT, and improve the treatment capability in the film deposition treatment provided by injecting the raw material mist MT.

In the present embodiment, a mist injecting distance D1 (see FIG. 1), which is a vertical distance in the injection region R1 between the injecting surface 1S in which the mist injection port for injecting the raw material mist from the thin film forming nozzle 1 is formed and the upper surface of the substrate 10 (placed on the substrate loading stages 3A and 3B), is set to 1 mm or more and 30 mm or less.

Thus, in the film deposition apparatus of the present embodiment, the mist injecting distance D1 of the thin film forming nozzle 1 is set to 1 mm or more and 30 mm or less, which makes it possible to more precisely perform the film deposition treatment provided by injecting the raw material mist MT.

<Other>

In the present embodiment, the two substrate loading stages 3A and 3B are shown as the substrate placing portion. However, the film deposition apparatus using four or more substrate loading stages 3 can also be achieved by improvements such as the provision of two substrate loading stages 3 in each of the transferring mechanisms 8L and 8R. However, as in the present embodiment, the achievement of the film deposition apparatus with only the two substrate loading stages 3A and 3B minimizes the number of the substrate loading stages 3, and is excellent in terms of the cost of the apparatus such as the simplification of the structure of the substrate transferring mechanism 8 which is the substrate placing portion transferring device, or the ease of the control contents of the circulating transporting treatment.

Each of the suction grippers 4A and 4B may have the heating mechanism, which provides an improved film deposition treatment so as to perform the heating treatment for the substrate 10 even during the substrate introducing operation M5 and the substrate retrieving operation M6.

While the present invention has been described in detail, the foregoing description is in all aspects illustrative, and the present invention is not limited thereto. It is understood that numerous modifications not illustrated can be devised without departing from the scope of the present invention.

### EXPLANATION OF REFERENCE SIGNS

1: thin film forming nozzle

3, 3A, 3B: substrate loading stage

4A, 4B: suction gripper

4: suction gripper

5: substrate introducing portion

6: substrate retrieving portion

8: substrate transferring mechanism

10: substrate

31: suction mechanism

32: heating mechanism

41A, 41B: suction mechanism

1. A film deposition apparatus comprising:
first and second substrate placing portions which place a substrate and include a suction mechanism for suctioning the placed substrate and a heating mechanism for heating the placed substrate;
a film deposition treatment executing portion which executes a film deposition treatment for depositing a thin film for the substrate placed on the substrate placing portion in a film deposition treatment region; and
a substrate placing portion transferring device which executes a transporting operation for moving the first and second substrate placing portions to cause the substrate placing portions to sequentially pass through the film deposition treatment region at a moving speed during film deposition, wherein
the transporting operation includes a circulating transporting treatment for circulating and arranging one substrate placing portion of the first and second substrate placing portions causing all the placed substrates to pass through the film deposition treatment region at a circulating speed behind the other substrate placing portion.

2. The film deposition apparatus according to claim 1, wherein an average value of the circulating speed is higher than the moving speed during film deposition.

3. The film deposition apparatus according to claim 2, wherein
each of the first and second substrate placing portions places a predetermined number of substrates, and
the predetermined number is set such that the circulating transporting treatment is completed until all the substrates placed on the other substrate placing portion pass through the film deposition treatment region.

4. The film deposition apparatus according to claim 1, wherein the substrate placed on the first and second substrate placing portions is a silicon substrate.

5. The film deposition apparatus according to claim 1, wherein
the film deposition treatment executing portion includes a mist injecting portion which injects a raw material mist obtained by misting a raw material solution into the air to execute the depositing treatment, and
the film deposition treatment region is an injection region of the raw material mist.

6. The film deposition apparatus according to claim 5, wherein
the mist injecting portion includes an injecting surface in which a mist injection port for injecting the raw material mist is formed, and
a mist injecting distance, which is a distance in the injection region between the injecting surface and the substrate placed on the first and second substrate placing portions, is set to 1 mm or more and 30 mm or less.
